(19) United States
(12) Patent Application Publication
(10) Pub. No.: US 2024/0397797 A1
(43) Pub. Date: Nov. 28, 2024

(54) ELECTRO-OPTICAL DEVICE AND ELECTRONIC APPARATUS

(71) Applicant: SEIKO EPSON CORPORATION, Tokyo (JP)

(72) Inventor: Takehiko KUBOTA, MATSUMOTO-SHI (JP)

(73) Assignee: SEIKO EPSON CORPORATION, Tokyo (JP)

(21) Appl. No.: 18/673,326

(22) Filed: May 24, 2024

(30) Foreign Application Priority Data
May 25, 2023 (JP) 2023-086312

(51) Int. Cl. H10K 59/80; G02B 27/01

(52) U.S. Cl. CPC H10K 59/878; G02B 27/0172; G02B 2027/0178

(57) ABSTRACT

An electro-optical device includes a transflective first electrode, a first reflective layer, a first pixel electrode provided between the first electrode and the first reflective layer, a second reflective layer, a second pixel electrode provided between the first electrode and the second reflective layer, a light-emitting layer provided between the first electrode, and the first pixel electrode and the second pixel electrode, and an insulating layer provided between the first pixel electrode and the first reflective layer. The insulating layer extends from the first pixel electrode and between the first pixel electrode and the second pixel electrode in plan view. A surface of the insulating layer on the light-emitting layer side includes a plurality of steps between the first pixel electrode and the second pixel electrode in plan view.

The present application is based on, and claims priority from JP Application Serial Number 2023-086312, filed May 25, 2023, the disclosure of which is hereby incorporated by reference herein in its entirety.

### BACKGROUND

### 1. Technical Field

The present disclosure relates to an electro-optical device and electronic apparatus.

### 2. Related Art

In recent years, development of an electro-optical device in which a light-emitting element called an organic light emitting diode (OLED) such as an organic electroluminescent (EL) element or a light-emitting polymer element has been advanced. JP 2019-029188 A discloses an electro-optical device provided with a plurality of sub-pixels. In the electro-optical device disclosed in JP 2019-029188 A, an optical resonant structure is formed for each sub-pixel by a reflective layer and a counter electrode. First distance adjustment layers and second distance adjustment layers are stacked at some sub-pixels that emit red light of the electro-optical device disclosed in JP 2019-029188 A. The second distance adjustment layers are stacked at some other sub-pixels that emit green light.

In the electro-optical device disclosed in JP 2019-029188 A described above, in a region between the sub-pixel emitting red light and an adjacent sub-pixel, there was a portion where an interval between the first and second distance adjustment layers and the counter electrode disposed sandwiching a light-emitting layer therebetween in a thickness direction of a substrate is locally smaller than an interval between an optical distance adjustment layer and the counter electrode in a region where the sub-pixels are disposed. When there is such a portion where the film thickness of the light-emitting layer is locally reduced in a periphery of an opening region of the sub-pixel in plan view as described above, resistance of the portion is lower than that of a portion where the light-emitting layer is thick, and a current flows between a positive electrode and a negative electrode. This causes unnecessary peripheral light emission in the peripheral region of the opening region of the sub-pixel. In a region closer to an element substrate than a portion where peripheral light is emitted, a layer structure different from an opening region of a sub-pixel adjacent to the portion is provided. Therefore, color light of the peripheral light emission is different from any color light of three primary colors emitted from the opening region of the sub-pixel. In particular, at the time of low-gradation display, when an amount of the peripheral light emission is not negligible compared with an amount of light emission due to the current flowing through the opening region of the sub-pixel, a color of the peripheral light emission becomes a mixture of colors emitted from opening regions of a plurality of adjacent sub-pixels, for example, and thus there is a problem in that color reproducibility of the electro-optical device decreases.

### SUMMARY

An electro-optical device of an aspect of the present disclosure includes a transflective first electrode, a first reflective layer, a first pixel electrode provided between the first electrode and the first reflective layer, a second reflective layer, a second pixel electrode provided between the first electrode and the second reflective layer, a light-emitting layer provided between the first electrode, and the first pixel electrode and the second pixel electrode, and an insulating layer provided between the first pixel electrode and the first reflective layer. The insulating layer extends from the first pixel electrode and between the first pixel electrode and the second pixel electrode in plan view. A surface of the insulating layer on the light-emitting layer side includes a plurality of steps between the first pixel electrode and the second pixel electrode in plan view.

### BRIEF DESCRIPTION OF THE DRAWINGS

FIG. 1 is a schematic view illustrating a configuration of an electro-optical device of an embodiment of the disclosure.

FIG. 2 is an equivalent circuit diagram of the electro-optical device of FIG. 1.

FIG. 3 is a plan view of a main part of the electro-optical device of FIG. 1.

FIG. 4 is a cross-sectional view of a main part of the electro-optical device of FIG. 1.

FIG. 5 is a cross-sectional view illustrating a manufacturing process of a main part of the electro-optical device of FIG. 1.

FIG. 6 is a cross-sectional view illustrating a manufacturing process of the main part of the electro-optical device of FIG. 1.

FIG. 7 is a cross-sectional view illustrating a manufacturing process of the main part of the electro-optical device of FIG. 1.

FIG. 8 is a cross-sectional view illustrating a manufacturing process of the main part of the electro-optical device of FIG. 1.

FIG. 9 is a cross-sectional view illustrating a manufacturing process of the main part of the electro-optical device of FIG. 1.

FIG. 10 is a cross-sectional view illustrating a manufacturing process of the main part of the electro-optical device of FIG. 1.

FIG. 11 is a cross-sectional view illustrating a manufacturing process of the main part of the electro-optical device of FIG. 1.

FIG. 12 is a cross-sectional view illustrating a manufacturing process of the main part of the electro-optical device of FIG. 1.

FIG. 13 is a plan view of a main part of an electro-optical device of the related art.

FIG. 14 is a cross-sectional view of a main part of the electro-optical device of the related art.

FIG. 15 is a schematic view of an electronic apparatus of an embodiment of the present disclosure.

FIG. 16 is a schematic view of an electronic apparatus of an embodiment of the present disclosure.

### DESCRIPTION OF EMBODIMENTS

With reference to the drawings, an embodiment of the present disclosure is described below. In each of the drawings, the scale of the dimensions may be changed depending on the components in order to make each of the components easier to see.

### Electro-Optical Device

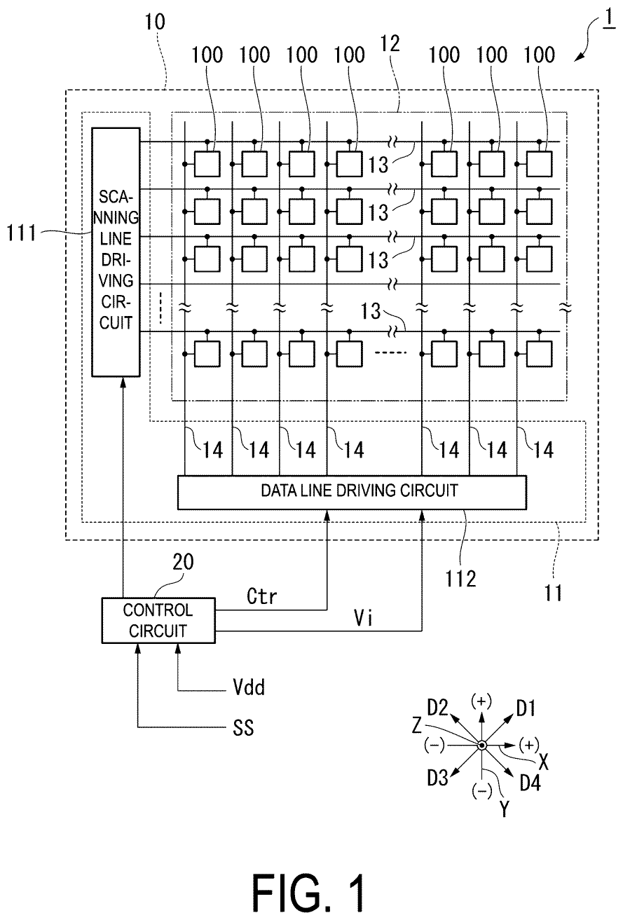

FIG. 1 is a schematic view illustrating an example of a configuration of an electro-optical device 1 of the embodiment. As illustrated in FIG. 1, the electro-optical device 1 includes a display panel 10 including a plurality of pixels Px and a control circuit 20 configured to control operation of the display panel 10. The sub-pixel Px is not illustrated in FIG. 1, but will be described in detail later.

Image data Vdd is supplied to the control circuit 20 in synchronization with a synchronization signal SS by a higher-level device (not illustrated). The image data Vdd is digital data that defines a gray scale level to be displayed by each pixel Px of the display panel 10. The synchronization signal SS is a signal including a vertical synchronization signal, a horizontal synchronization signal, a dot clock signal, and the like. The control circuit 20 generates a control signal Ctr for controlling operation of the display panel 10, based on the synchronization signal SS, and supplies the control signal Ctr to the display panel 10. The control circuit 20 generates an analog image signal Vi, based on the image data Vdd, and supplies the image signal Vi to the display panel 10. The image signal Vi is a signal that defines a luminance of a light-emitting element included in the sub-pixel Px so that each sub-pixel Px displays gradation designated by the image data Vdd.

The display panel 10 includes a scanning line 13, a data line 14, a display unit 12 and a driving circuit 11. The M scanning lines 13 are provided, and extend along an X-axis, for example. The (3×N) data lines 14 are provided, and extend along a Y-axis orthogonal to the X-axis. Note that M is a natural number equal to or greater than 1, and N is a natural number equal to or greater than 1. The display unit 12 includes (M×3×N) pixel circuits 100 disposed at intersection positions of the M scanning lines 13 and the (3×N) data lines 14. The driving circuit 11 drives the display unit 12.

Hereinafter, in order to distinguish respective numbers of the plurality of sub-pixels Px, the plurality of scanning lines 13, and the plurality of data lines 14 from each other, rows are referred to as a first row, a second row, . . . and an M-th row in order from a +Y direction to a −Y direction in the Y-axis. Further, columns are referred to as a first column, a second column, . . . , and a 3N-th column in order from a −X direction to a +X direction in the X-axis. Hereinafter, one direction along a Z-axis intersecting the X-axis and the Y-axis is referred to as a +Z direction or an upward direction, and an opposite direction is referred to as a −Z direction or a downward direction. Viewing along the Z-axis may be referred to as “in plan view”.

A plane including the X-axis and the Y-axis is a plane on which the plurality of pixel circuits 100 of the display unit 12 are disposed. A direction inclined at angles equal to each other with respect to both the +X direction and the +Y direction in plan view is defined as a D1 direction. A direction inclined at angles equal to each other with respect to both the −X direction and the +Y direction in plan view is defined as a D2 direction. A direction inclined at angles equal to each other with respect to both the −X direction and the −Y direction in plan view is defined as a D3 direction. A direction, between the +X direction and the −Y direction, inclined at angles equal to each other with respect to both the +X direction and the −Y direction in plan view is defined as a D4 direction.

The plurality of pixel circuits 100 include a pixel circuit 100R capable of displaying red, a pixel circuit 100G capable of displaying green, and a pixel circuit 100B capable of displaying blue. In the embodiment, n is a natural number satisfying 1≤n≤N. For example, among the first column to a (3×N)th column, the pixel circuit 100R is disposed in a (3n−2)th column, the pixel circuit 100G is disposed in a (3n−1)th column, and the pixel circuit 100B is disposed in a 3n-th column.

The driving circuit 11 includes a scanning line driving circuit 11 and a data line driving circuit 12. The scanning line driving circuit 111 scans the scanning lines 13 from the first row to the M-th row in order and selects the scanning lines. Specifically, in a period of one frame, the scanning line driving circuit 111 sets scanning signals Gw[1] to Gw[M] output to the respective scanning lines 13 in the first row to the M-th row to a predetermined selection potential sequentially for each horizontal scanning period. Thus, the scanning line driving circuit 111 sequentially selects the scanning lines 13 row by row for each horizontal scanning period. That is, the scanning line driving circuit 111 selects the scanning line 13 in an m-th row by setting a scanning signal Gw[m] output to the scanning line 13 in the m-th row to the predetermined selection potential in an m-th horizontal scanning period in a period of one frame. Note that a frame of one period means a period in which the electro-optical device 1 displays one image.

The data line driving circuit 112 generates analog data signals Vd[1] to Vd[3×N] that define gradation displayed by the respective pixel circuits 100 based on the image signal Vi and the control signal Ctr supplied from the control circuit 20. The data line driving circuit 112 outputs the generated data signals Vd[1] to Vd[3×N] to the (3×N) data lines 14 for each horizontal scanning period. That is, the data line driving circuit 112 outputs a data signal Vd[k] to the data line 14 in a k-th column in each horizontal scanning period. Although the image signal Vi output from the control circuit 20 is an analog signal in the embodiment, the image signal Vi output from the control circuit 20 may be a digital signal. When the image signal Vi is a digital signal, the data line driving circuit 112 performs digital/analog conversion on the image signal Vi to generate the analog data signals Vd[1] to Vd[3×N].

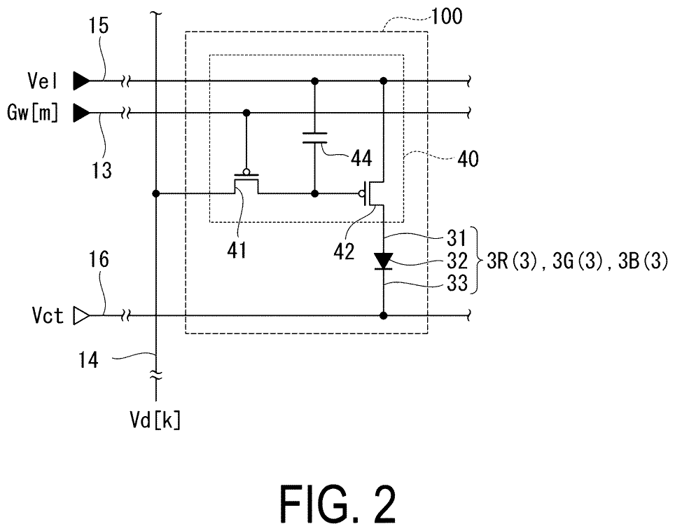

FIG. 2 is an equivalent circuit diagram of the pixel circuit 100. FIG. 2 illustrates the pixel circuit 100 in the m-th row and the k-th column. As illustrated in FIG. 2, the pixel circuit 100 includes a light-emitting element 3 and a supply circuit 40 that outputs a current to be supplied to the light-emitting element 3.

The light-emitting element 3 includes a pixel electrode 31, a light-emitting layer 32, and a counter electrode 33. The pixel electrode 31 functions as a positive electrode that supplies holes into the light-emitting layer 32. The counter electrode 33 is electrically coupled to a power supply line 16 set to a potential Vct which is a power supply potential on a low potential side of the pixel circuit 100. The counter electrode 33 functions as a negative electrode that supplies electrons to the light-emitting layer 32. The holes supplied from the pixel electrode 31 and the electrons supplied from the counter electrode 33 are combined in the light-emitting layer 32, and the light-emitting layer 32 emits white light.

As will be described later, a red color filter is disposed and overlaid at a light-emitting element 3R included in the pixel circuit 100R in plan view. A blue color filter is disposed and overlaid at a light-emitting element 3B included in the pixel circuit 100B in plan view. A green color filter is disposed and overlaid at a light-emitting element 3G included in the pixel circuit 100G in plan view. Therefore, full-color display is achieved by the light-emitting elements 3R, 3G, and 3B.

The supply circuit 40 includes a P-channel transistors 41, 42, and a retention capacitor 44. It should be noted that at least one of the transistors 41 and 42 may be an N-channel transistor. In the embodiment, the transistors 41 and 42 are each a thin film transistor (TFT). The transistors 41 and 42 may each be a field effect transistor such as a metal-oxide-semiconductor field-effect transistor (MOSFET).

A gate of the transistor 41 is electrically coupled to the scanning line 13 in the m-th row. One of a source and a drain of the transistor 41 is electrically coupled to the data line 14 in the k-th column. Further, another of the source and the drain of the transistor 41 is electrically coupled to a gate of the transistor 42, and one electrode of two electrodes included in the retention capacitor 44.

The gate of the transistor 42 is electrically coupled to the other of the source and the drain of the transistor 41, and the one electrode of the retention capacitor 44. One of a source and a drain of the transistor 42 is electrically coupled to the pixel electrode 31. Another of the source and the drain of the transistor 42 is electrically coupled to the power supply line 15 set to a potential Vel which is a power supply potential on a high potential side of the pixel circuit 100.

The retention capacitor 44 includes the two electrodes. The one electrode of the retention capacitor 44 is electrically coupled to the other of the source and the drain of the transistor 41, and the gate of the transistor 42. Further, another electrode of the retention capacitor 44 is electrically coupled to the power supply line 15. The retention capacitor 44 functions as a retention capacitor that holds a potential of the gate of the transistor 42.

When the scanning line driving circuit 111 sets the scanning signal Gw[m] to the predetermined selection potential and selects the scanning line 13 in the m-th row, the transistor 41 provided at a sub-pixel Px[m] [k] in the m-th row and the k-th column is in an on state. Hereinafter, the sub-pixel Px[m] [k] may be simply referred to as a sub-pixel Px. When the transistor 41 is in the on state, the data signal Vd[k] is supplied from the data line 14 in the k-th column to the gate of the transistor 42. In this case, the transistor 42 supplies a current corresponding to a potential of the data signal Vd[k] supplied to the gate to the light-emitting element 3. The data signal Vd[k] corresponds to a potential difference between the gate and the source. That is, the transistor 42 is a drive transistor that supplies a current to the light-emitting element 3. The light-emitting element 3 emits light at a luminance corresponding to a magnitude of the current supplied from the transistor 42, that is, a luminance corresponding to the potential of the data signal Vd[k].

Next, when the scanning line driving circuit 111 releases the selection of the scanning line 13 in the m-th row, and the transistor 41 is in an off state, the potential of the gate of the transistor 42 is held by the retention capacitor 44. The light-emitting element 3 emits light at a luminance corresponding to the data signal Vd[k] even after the transistor 41 is in the off state.

Although omitted in FIG. 2, a component that electrically couples the pixel electrode 31 included in the light-emitting element 3 and the supply circuit 40 is referred to as a contact 7. Each sub-pixel Px includes the light-emitting element 3, the supply circuit 40, and a contact area CA in which the contact 7 is disposed. The contact area CA is an area in which the contact 7 can be disposed. The contact 7 electrically couples the pixel electrode 31 included in the light-emitting element 3 and the supply circuit 40.

Hereinafter, the contact 7 provided at a sub-pixel PxR emitting red light is referred to as a contact 7R. The contact 7 provided at a sub-pixel PxG emitting green light is referred to as a contact 7G. The contact 7 provided at a sub-pixel PxB emitting blue light may be referred to as a contact 7B. Hereinafter, the contact area CA in which the contact 7R is disposed is referred to as a contact area CR. The contact area CA in which the contact 7G is disposed is referred to as a contact area CG. The contact area CA in which the contact 7B is disposed is referred to as a contact area CB.

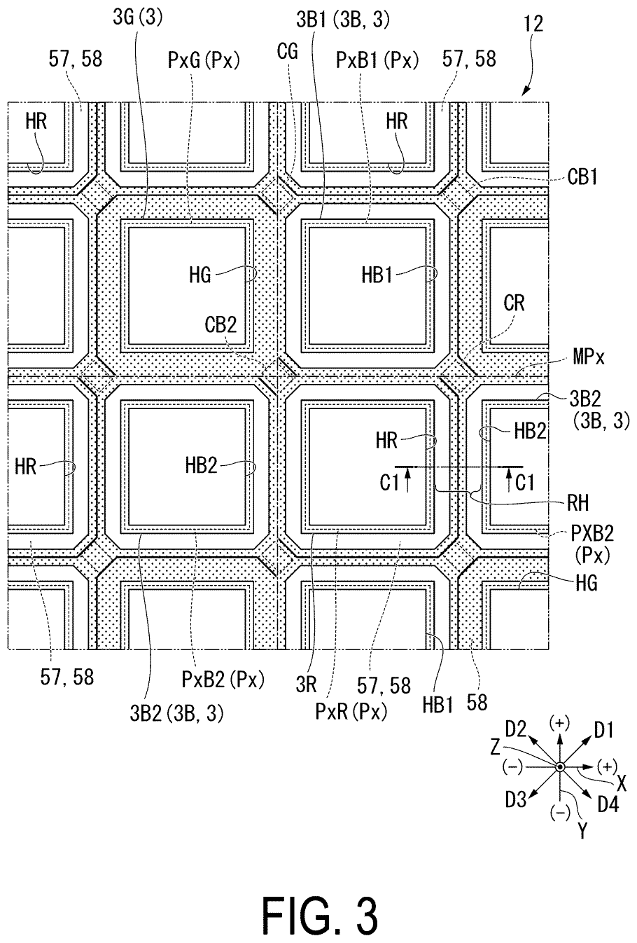

FIG. 3 is a plan view of a part of the display unit 12, and is a diagram in plan view from the +Z direction. In FIG. 3, the color filters are omitted. FIG. 3 illustrates the sub-pixel PxR, the sub-pixel PxG, a sub-pixel PxB1, and a sub-pixel PxB2 constituting a pixel MPx in the display unit 12. The sub-pixel PxR includes the light-emitting element 3R of the pixel circuit 100R capable of displaying red. The sub-pixel PxG includes the light-emitting element 3G of the pixel circuit 100G capable of displaying green. The sub-pixel PxB1 includes a light-emitting element 3B1 of the pixel circuit 100B capable of displaying blue. The sub-pixel PxB2 includes a light-emitting element 3B2 of the pixel circuit 100B. A current is supplied to the sub-pixels PxB1 and PxB2 from the supply circuit 40 included in the same pixel circuit 100B.

In the pixel MPx, the sub-pixels PxR and PxB2 are sequentially disposed along the +X direction, and the sub-pixels PxB1 and PxG are sequentially disposed along the +X direction in a region on the −Y direction side of these sub-pixels. In the pixel MPx, the sub-pixels PxB1 and PxR are sequentially disposed along the +Y direction, and the sub-pixels PxG and PxB2 are disposed along the +Y direction in a region on the +X direction side of these sub-pixels. The sub-pixel PxB1 is coupled to the sub-pixel PxB2 located on the D1 direction side when viewed from the sub-pixel PxB1 by a reflective layer 52 to be described later. The light-emitting elements 3R, 3G, 3B1, and 3B2 included in the pixel MPx form light-emitting regions HR, HG, HB1, and HB2 that emit light to regions on the +Z direction side, respectively. The light-emitting regions HR, HG, HB1, and HB2 are regions opened by a pixel separation layer 34 in regions of the pixel electrode 31.

Each of the light-emitting regions HR, HG, HB1, and HB2 has a rectangular shape in plan view. The shape of each of the light-emitting regions HR, HG, HB1, and HB2 in plan view may be, for example, an octagon or the like. Hereinafter, the light-emitting regions HR, HG, HB1, and HB2 may be collectively referred to as a light-emitting region HA.

The contact area CA included in the sub-pixel Px is located in the D1 direction when viewed from the light-emitting region HA included in the sub-pixel Px. To be specific, the contact area CR of the sub-pixel PxR is located in the D1 direction of the light-emitting region HR of the sub-pixel PxR, and is provided between the light-emitting region HR and the light-emitting region HG of the sub-pixel PxG in the D1 direction. Similarly, the contact area CG of the sub-pixel PxG is located in the D1 direction of the light-emitting region HG of the sub-pixel PxG, and is provided between the light-emitting region HG and the light-emitting region HR of the sub-pixel PxR in the D1 direction. A contact area CB1 of the sub-pixel PxB1 is located in the D1 direction of the light-emitting region HB1 of the sub-pixel PxB1, and is provided between the light-emitting region HB1 and the light-emitting region HB2 of the sub-pixel PxB2 in the D1 direction. A contact area CB2 of the sub-pixel PxB2 is located in the D1 direction of the light-emitting region HB2 of the sub-pixel PxB2, and is provided between the light-emitting region HB2 and the light-emitting region HB1 of the sub-pixel PxB1 in the D1 direction.

As described above, the plurality of contact areas CA are disposed along the D1 direction. A contact electrode (not illustrated) that electrically couples the pixel electrode 31 and the reflective layer 52 via a contact electrode 71 is formed in each of the contact areas CB1 and CB2. In the contact area CR, a contact electrode (not illustrated) that electrically couples the reflective layer 52 and the contact electrode 71, and a contact electrode (not illustrated) that electrically couples the contact electrode 71 and the pixel electrode 31 are individually formed. Similarly, in the contact area CG, a contact electrode (not illustrated) that electrically couples the reflective layer 52 and the contact electrode 71, and a contact electrode (not illustrated) that electrically couples the contact electrode 71 and the pixel electrode 31 are individually formed.

The red color filter (not illustrated in FIG. 3) is provided on the +Z direction side of the light-emitting element 3R, and is formed so as to overlap at least the sub-pixel PxR in plan view. The green color filter (not illustrated) is provided on the +Z direction side of the light-emitting element 3G, and is formed so as to overlap at least the sub-pixel PxG in plan view. The blue color filter (not illustrated) is provided on the +Z direction side of the light-emitting element 3B1, and is formed so as to overlap at least the sub-pixel PxB1 in plan view. The blue color filter (not illustrated) that is different from the above is provided on the +Z direction side of the light-emitting element 3B2, and is formed so as to overlap at least the sub-pixel PxB2 in plan view.

The display unit 12 includes an element substrate 5, a counter substrate, and an adhesive layer, which will be described later, in the Z-axis direction. In the electro-optical device 1, a top emission system is employed in which light is emitted to the +Z direction side from a plate surface on a side opposite to a plate surface in contact with the adhesive layer in the counter substrate.

A detailed structure of the element substrate 5 will be described below. The counter substrate is disposed on the +Z direction side of the element substrate 5 via the adhesive layer in the Z-axis. The counter substrate is a transparent substrate disposed on the +Z direction side of the adhesive layer. The counter substrate protects a layer structure including a color filter of each color disposed on the −Z direction side of the counter substrate. The adhesive layer is a transparent resin layer for bonding the element substrate 5 and the counter substrate. For example, a transparent resin material such as an epoxy resin is used for the adhesive layer. For the counter substrate, for example, a quartz substrate is used.

The element substrate 5 includes a substrate, a circuit layer, an interlayer insulating layer 51, a conductive layer 151, a conductive layer 152, an insulating layer 153, an insulating layer 154, an insulating layer 155, an insulating layer 157, an insulating layer 158, a conductive layer 131, a conductive layer 132, a conductive layer 133, an insulating layer 134, a sealing layer 60, and a color filter layer.

The substrate described above is a substrate on which various wirings and various circuits can be mounted. A type of the substrate is not particularly limited. For example, the substrate is a silicon substrate, a quartz substrate, a glass substrate, or the like. The circuit layer is formed on the +Z direction side of the above substrate. The circuit layer includes various wirings such as the scanning lines 13 and the data lines 14, switching elements such as thin film transistors, and various circuits such as the driving circuit 11 and the pixel circuit 100. The interlayer insulating layer 51 is stacked on the +Z direction side of the circuit layer.

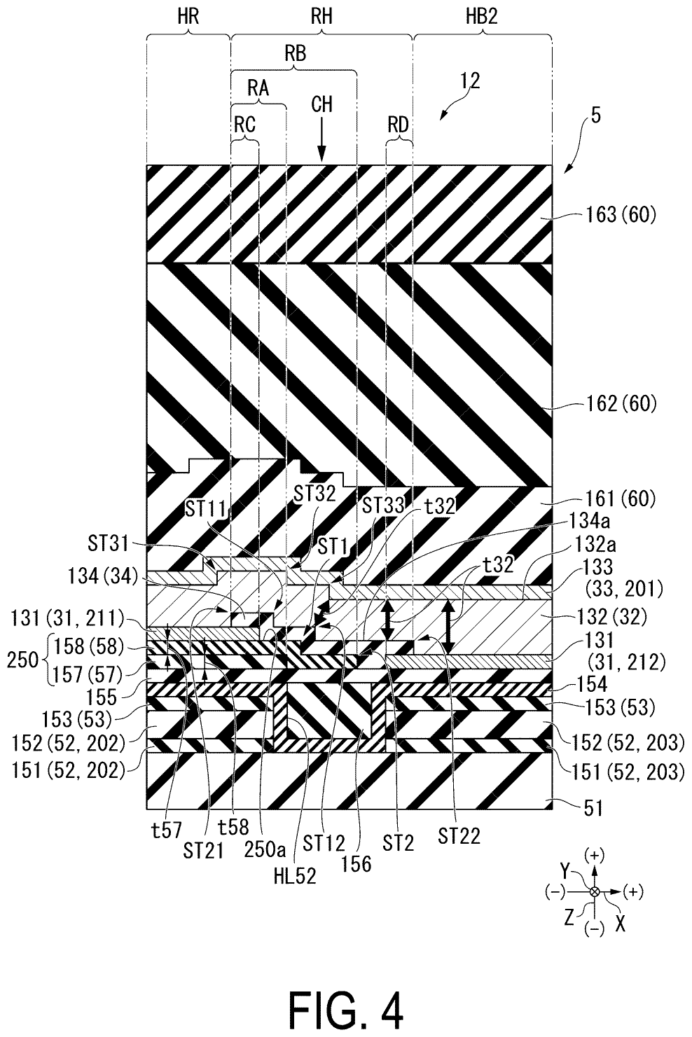

FIG. 4 is a cross-sectional view of a part of the display unit 12, taken along a line C1-C1 illustrated in FIG. 3. A region indicated by the line C1-C1 in FIG. 3 includes an end portion of the light-emitting region HR of red light on the +X direction side and an end portion of the light-emitting region HB2 of blue light on the −X direction side, which are adjacent to each other in the X-axis, and a peripheral region RH forming a boundary between the light-emitting regions HR and HB2. FIG. 4 illustrates a stacked structure of the interlayer insulating layer 51 to an insulating layer 163 in the structure along the Z-axis of the display unit 12.

A material of the interlayer insulating layer 51 is silicon oxide (SiO: layer), for example. The conductive layer 151 is stacked on the +Z direction side of the interlayer insulating layer 51, and is formed in substantially an entire region illustrated in FIG. 4. The conductive layer 152 is stacked on the +Z direction side of the conductive layer 151, and is formed in substantially the entire region illustrated in FIG. 4. The conductive layer 151 or 152 is individually formed in an island shape for each sub-pixel Px in plan view, and have reflectivity with respect to light emitted from the light-emitting element 3 of the light-emitting layer 32. The conductive layer 151 is formed of, for example, a titanium (Ti) film. The conductive layer 152 is formed of, for example, a composite film of a titanium (Ti) film and an alloy (AlCu) film of aluminum (Al) and copper (Cu) stacked thereon. A stacked structure formed of the conductive layers 151 and 152 constitutes the reflective layer 52, and reflects light emitted to the −Z direction side out of light emitted from the light-emitting element 3 included in the light-emitting layer 32 to the +Z direction side.

The insulating layer 153 is stacked on the +Z direction side of the conductive layer 151, and is formed in substantially the entire region illustrated in FIG. 4. The insulating layer 153 constitutes a reflection enhancing layer 53, is provided to enhance reflection characteristics of light by the reflective layer 52, and is formed of an insulating material having optical transparency. As an insulating material having optical transparency, for example, silicon oxide is given.

The insulating layer 154 is formed so as to cover a front surface parallel to the X-axis and the Y-axis of the insulating layer 153, and a sidewall surface and a bottom wall surface of a hole HL52. The hole HL52 is formed between the light-emitting region HR and the light-emitting region HB2 in the X-axis, and penetrates the conductive layers 151, 152, and the insulating layer 153 in the Z-axis. That is, a concave portion along the hole HL52 is formed at the insulating layer 154. A sidewall of the hole HL52 is in contact with the conductive layers 151, 152, and the insulating layer 153. The interlayer insulating layer 51 is in contact with a bottom of the hole HL52. The insulating layer 154 is formed of, for example, a silicon nitride (SiN) film.

The insulating layer 156 is embedded in the concave portion of the insulating layer 154 formed at the hole HL52 as described above. A front surface of the insulating layer 156 parallel to the X-axis and the Y-axis, and the insulating layer 155 are flush with a front surface of the insulating layer 154 parallel to the X-axis and the Y-axis. The insulating layer 156 is formed of, for example, silicon oxide.

The insulating layer 155 is formed so as to cover the front surface of the insulating layer 154 parallel to the X-axis and the Y-axis, and the front surface of the insulating layer 156 parallel to the X-axis and the Y-axis in substantially the entire region illustrated in FIG. 4. The insulating layer 155 is formed of, for example, a silicon nitride film.

The insulating layer 157 is formed at least in the light-emitting region HR, and is formed at a front surface parallel to the X-axis and the Y-axis of the insulating layer 155 in the light-emitting region HR. The insulating layer 157 is further formed at the front surface parallel to the X-axis and the Y-axis of the insulating layer 155 in a peripheral region RA of the light-emitting region HR, and is integrally formed with the insulating layer 157 of the light-emitting region HR. The peripheral region RA is a region of a boundary region RH between the light-emitting region HR and the light-emitting region HB1 or HB2 on a side close to the light-emitting region HR in plan view. In plan view, an end of the peripheral region RA on the light-emitting region HB2 side, that is, an end of the insulating layer 158 on the light-emitting region HB2 side is disposed closer to the light-emitting region HR side than an intermediate position CH in the X-axis of the peripheral region RH, and overlaps the insulating layer 154 or the insulating layer 156 embedded in the hole HL52. The insulating layer 157 is not formed at least in the light-emitting region HB1 or HB2. The insulating layer 157 is formed of, for example, silicon oxide.

The insulating layer 158 is formed at least in the light-emitting region HR or HG, and is formed at a front surface parallel to the X-axis and the Y-axis of the insulating layer 157 in the light-emitting region HR and at the front surface parallel to the X-axis and the Y-axis of the insulating layer 155 in the light-emitting region HG. The insulating layer 158 covers the insulating layer 157 in the light-emitting region HR and the peripheral region RA, is further formed at the front surface parallel to the X-axis and the Y-axis of the insulating layer 155 or 157 in a peripheral region RB, and is integrally formed with the insulating layer 158 in the light-emitting region HR. The insulating layer 158 covers the insulating layer 155 in the light-emitting region HG, is further formed at the front surface parallel to the X-axis and the Y-axis of the insulating layer 155 in the peripheral region RB, and is integrally formed with the insulating layer 158 in the light-emitting region HG. The peripheral region RB is a region of the boundary region RH on a side close to the light-emitting region HB1 or HB2 in plan view, and is a region that overlaps the peripheral region RA on the light-emitting region HR side, and extends to the light-emitting region HB1 or HB2 side with respect to the peripheral region RA in plan view. In plan view, an end of the peripheral region RB on the light-emitting region HB2 side, that is, an end of the insulating layer 157 on the light-emitting region HB2 side is disposed closer to the light-emitting region HB2 side than the intermediate position CH in the X-axis of the peripheral region RH, and overlaps the insulating layer 154 or the insulating layer 156 embedded in the hole HL52. The insulating layer 158 is not formed at least in the light-emitting region HB1 or HB2. The insulating layer 158 is formed of the same insulating material as that of the insulating layer 157, for example, silicon oxide.

The conductive layer 131 is formed at least at a front surface parallel to the X-axis and the Y-axis of the insulating layer 158 in a region overlapping the light-emitting region HR or HG in plan view, and is formed at the front surface parallel to the X-axis and the Y-axis of the insulating layer 155 in a region overlapping the light-emitting region HB1 or HB2 in plan view. The conductive layer 131 is further formed at the front surface parallel to the X-axis and the Y-axis of the insulating layer 158 in a peripheral region RC, and is formed integrally with the conductive layer 131 in the light-emitting region HR or HG. The peripheral region RC is a region of the boundary region RH which is closer to the light-emitting region HR or HG in plan view, overlaps the peripheral region RA, and is a region of the peripheral region RA which is close to the light-emitting region HR or HG in plan view. The conductive layer 131 is further formed at the front surface parallel to the X-axis and the Y-axis of the insulating layer 155 in a peripheral region RD, and is formed integrally with the conductive layer 131 in the light-emitting region HB1 or HB2. The peripheral region RD is a region of a boundary region R on a side close to the light-emitting region HB1 or HB2 in plan view, and is a region separated from the peripheral region RB in plan view. A width of the peripheral region RD in the X-axis or the Y-axis is equivalent to a width of the peripheral region RC in the X-axis or the Y-axis. The conductive layer 131 is formed of a conductive transparent material, and is formed of indium tin oxide (ITO), for example. The conductive layer 131 forms the pixel electrode 31 in the display unit 12.

The insulating layer 134 is formed in the peripheral region RH in plan view. The insulating layer 134 is formed at the front surface parallel to the X-axis and the Y-axis of each of the conductive layer 131 in the peripheral region RC, the insulating layer 158 in the peripheral region RB closer to the light-emitting region HB1 or HB2 than the peripheral region RC, the insulating layer 155 in a region between the peripheral region RB and the peripheral region RD in plan view, and the conductive layer 131 in the peripheral region RD, and covers these front surfaces from the +Z direction side. The insulating layer 134 is formed of, for example, silicon oxide. The insulating layer 134 partitions the light-emitting regions HR, HG, HB1, and HB2 from each other in plan view, separates the sub-pixels Px, and configures the pixel separation layer 34 in the display unit 12.

In the Z-axis, the conductive layer 131 provided in the light-emitting region HB1 or HB2 is formed at the same position as the insulating layer 157 provided in the light-emitting regions HR, HG, and the peripheral region RA, and the insulating layer 158 provided in the peripheral region RB which does not overlap the peripheral region RA in plan view. In plan view, a peripheral edge of the insulating layer 157 is disposed outside a peripheral edge of the conductive layer 131 formed in the light-emitting region HR or HG, that is, on the light-emitting region HB1 or HB2 side. A peripheral edge of the insulating layer 158 disposed between the insulating layer 157 and the conductive layer 131 formed in the light-emitting region HR or HG in the Z-axis is disposed further outside than the peripheral edge of the insulating layer 157. Therefore, the insulating layer 158 includes a step ST1 descending toward the −Z direction side at a position overlapping the peripheral edge of the insulating layer 157 in plan view, that is, an end of the peripheral region RA on the light-emitting region HB1 or HB2 side in plan view. The insulating layer 158 includes a step ST2 due to an end on a side closest to the light-emitting region HB2 in plan view.

A position in the Z-axis of a front surface parallel to the X-axis and the Y-axis of the insulating layer 134 in a region of the peripheral region RA closer to the light-emitting region HB1 or HB2 than the peripheral region RC in plan view is moved to the −Z direction side from a position in the Z-axis of the front surface parallel to the X-axis and the Y-axis of the insulating layer 134 in the peripheral region RC by a height in the Z-axis corresponding to a thickness of the conductive layer 131 of the light-emitting region HR or HG. A position in the Z-axis of the front surface parallel to the X-axis and the Y-axis of the insulating layer 134 in a region of the peripheral region RB closer to the light-emitting region HB1 or HB2 than the peripheral region RA in plan view is moved in the −Z direction side from a position in the Z-axis of the front surface parallel to the X-axis and Y-axis of the insulating layer 134 in a region of the peripheral region RA closer to the light-emitting region HB1 or HB2 than the peripheral region RC in plan view by a height in the Z-axis corresponding to a thickness of the insulating layer 158 in the light-emitting regions HR, HG, and the peripheral region RA. A position in the Z-axis of the front surface parallel to the X-axis and the Y-axis of the insulating layer 134 is constant in a region of the peripheral region RH closer to the light-emitting region HB1 or HB2 than the peripheral region RB in plan view.

In the peripheral region RH, the insulating layer 134 includes a step ST11 descending toward the −Z direction side at a position overlapping the peripheral edge of the insulating layer 157 formed in the light-emitting region HR or HG in plan view, that is, an end of the peripheral region RC on the light-emitting region HB1 or HB2 side in plan view. The insulating layer 134 includes a step ST12 descending toward the −Z direction side at a position overlapping the step ST1 in plan view.

The conductive layer 132 is formed in substantially the entire region illustrated in FIG. 4 so as to cover a front surface parallel to the X-axis and the Y-axis of the conductive layer 131 provided in a region of each of the light-emitting regions HR, HG, HB1, and HB2, and the front surface parallel to the X-axis and the Y-axis of the insulating layer 134 in the peripheral region RH. The conductive layer 132 is disposed so as to span the plurality of sub-pixels Px. The conductive layer 132 includes a hole injection layer, a hole transport layer, an organic light-emitting layer, and an electron transport layer (not illustrated), and has a stacked structure in which the hole injection layer, the hole transport layer, the organic light-emitting layer, and the electron transport layer are sequentially stacked in the +Z direction. The conductive layer 132 constitutes the light-emitting layer 32 in the display unit 12. A thickness of each of the hole injection layer, the hole transport layer, the organic light-emitting layer, and the electron transport layer included in the conductive layer 132 is individually set to a predetermined thickness. Holes are supplied to the light-emitting layer 32 from a portion of the pixel electrode 31 which is not covered with the pixel separation layer 34. As a result, the light-emitting layer 32 emits white light. The white light includes red light, green light, and blue light.

The front surface parallel to the X-axis and the Y-axis of the conductive layer 131 provided in the light-emitting region HR or HG, the front surface parallel to the X-axis and the Y-axis of the insulating layer 134 in the peripheral region RH, and the front surface parallel to the X-axis and the Y-axis of the conductive layer 131 provided in the light-emitting region HB1 or HB2 are not flush with each other. For example, from the conductive layer 131 in the light-emitting region HR to an end portion of the insulating layer 134 on the light-emitting region HR side in plan view, a step ST21 ascending toward the +Z direction side is generated. From the conductive layer 131 in the light-emitting region HB1 to an end portion of the insulating layer 134 on the light-emitting region HB1 side in plan view, a step ST22 ascending toward the +Z direction side is generated. In the X-axis, steps ST11 and ST12 of the insulating layer 134 are generated between the steps ST21 and ST22. The conductive layer 132 has the stacked structure of the plurality of layers as described above, and each layer is deposited and formed above the conductive layer 131 and above the insulating layer 134 which are not flat in a plane parallel to the X-axis and the Y-axis. Therefore, a bottom surface on the −Z direction side and a front surface 132a on the +Z direction side of the conductive layer 132 each include the plurality of steps due to the steps ST1, ST2, ST11, ST12, ST21, and ST22, and are each not flat in a plane parallel to the X-axis and the Y-axis.

To be specific, the front surface 132a of the conductive layer 132 includes, for example, three steps ST31, ST32, and ST33. In the step ST31, the front surface 132a of the conductive layer 132 ascends toward the +Z direction side along the step ST21 as proceeding to the +X direction side from the light-emitting region HR or HG toward the light-emitting region HB1 or HB2. In the step ST32, the front surface 132a of the conductive layer 132 descends toward the −Z direction side along the step ST31 and the step ST11 of the insulating layer 134. In the step ST33, the front surface 132a of the conductive layer 132 descends toward the −Z direction side along the step ST1 of the insulating layer 158 and the step ST12 of the insulating layer 134.

The conductive layer 133 is formed in substantially the entire region illustrated in FIG. 4 so as to cover a front surface on the +Z direction side of the conductive layers 132 provided over the light-emitting regions HR, HG, HB1, and HB2, and the peripheral region RH. As in the case of the conductive layer 132, the conductive layer 133 includes a plurality of steps due to ST1, ST11, ST12, ST21, and ST22, and is not flat in a plane parallel to the X-axis and the Y-axis.

The conductive layer 133 has optical transparency and optical reflectivity, and is translucent to white light. The conductive layer 133 is formed of a translucent conductive layer containing, for example, magnesium (Mg) and silver (Ag). The conductive layer 133 constitutes the counter electrode 33 in the display unit 12. Here, the term “translucent” means that both characteristics of optical transparency and optical reflectivity coexist. A transmittance and a reflectance of light incident on the conductive layer 133 are not limited to specific values. For example, the transmittance of the conductive layer 133 is from 40% to 70%.

Although not illustrated in FIG. 4, a contact electrode is formed at a predetermined position in plan view in each of the light-emitting regions HR, HG, HB1, and HB2. The contact electrode electrically couples the pixel electrode 31 formed of the conductive layer 131 and the reflective layer 52 formed of the conductive layer 151 or 152 in each region.

The light-emitting layer 32 includes the light-emitting elements 3R, 3G, and 3B (not illustrated). Hereinafter, the light-emitting elements 3R, 3G, and 3B may be collectively referred to as a light-emitting element 3. The light-emitting element 3 emits light to the +Z direction side and the −Z direction side.

In the display unit 12, in plan view, a stacked structure included in each of the light-emitting regions HR, HG, HB1, and HB2, and the contact area CA corresponding to each light-emitting region corresponds to the sub-pixel Px.

The insulating layer 157 and the insulating layer 158 constitute a distance adjustment layer for adjusting an optical distance of color light in the Z-axis between the counter electrode 33 and the reflective layer 52 for each of the sub-pixels PxR, PxG, and PxB, that is, for each of the light-emitting region HR and HG and for each of the light-emitting region HB1 and HB2. The insulating layer 157 corresponds to a first optical distance adjustment layer 57. The insulating layer 158 corresponds to a second optical distance adjustment layer 58. A thickness t58 of the second optical distance adjustment layer 58 formed of the insulating layer 158 is substantially equal to a thickness t57 of the first optical distance adjustment layer 57 formed of the insulating layer 157, and may be smaller than the thickness t57. A difference between an optical distance in the Z-axis between the counter electrode 33 and the reflective layer 52 in the sub-pixel PxR, that is, the light-emitting region HR, and an optical distance in the Z-axis between the counter-electrode 33 and the reflective layer 52 in the sub-pixel PxB, that is, the light-emitting region HB1 or HB2, corresponds to an optical distance depending on a sum of a thickness in the Z-axis of the first optical distance adjustment layer 57 and a thickness in the Z-axis of the second optical distance adjustment layer 58. A difference between the optical distance in the Z-axis between the counter electrode 33 and the reflective layer 52 in the sub-pixel PxR, that is, the light-emitting region HR, and an optical distance in the Z-axis between the counter electrode 33 and the reflective layer 52 in the sub-pixel PxG, that is, the light-emitting region HG, corresponds to an optical distance dependent on the thickness of the first optical distance adjustment layer 57 in the Z-axis. A difference between the optical distance in the Z-axis between the counter electrode 33 and the reflective layer 52 in the sub-pixel PxG, that is, the light-emitting region HG, and the optical distance in the Z-axis between the counter electrode 33 and the reflective layer 52 in the sub-pixel PxB, that is, the light-emitting region HB1 or HB2, corresponds to an optical distance dependent on the thickness of the second optical distance adjustment layer 58 in the Z-axis.

The sealing layer 60 includes an insulating layer 161, an insulating layer 162, and an insulating layer 163. The insulating layer 161 is formed, in substantially the entire region illustrated in FIG. 4, at a front surface on the +Z direction side of the conductive layers 133 provided over the light-emitting regions HR or HG, HB1 or HB2, and the peripheral region RH. The insulating layer 162 is provided above the insulating layer 161. The insulating layer 163 is provided above the insulating layer 162. The insulating layer 161 or 163 of the sealing layer 60 is provided to prevent moisture, oxygen, or the like from entering the light-emitting layer 32. The insulating layer 162 includes a flat surface parallel to the X-axis and the Y-axis on the +Z direction side. The insulating layer 161 or 163 is formed of, for example, silicon oxynitride (SiON). The insulating layer 162 is formed of, for example, an inorganic material such as an epoxy resin.

The color filter layer includes a red, green, or blue color filter and is formed above the absolute layer 163 of the sealing layer 60.

In the display unit 12, the reflective layer 52 and the counter electrode 33 constitute an optical resonant structure. The thickness t57 of the first optical distance adjustment layer 57 and the thickness t58 of the second optical distance adjustment layer 58 are appropriately adjusted based on a peak wavelength of each of red light, green light, and blue light, the optical distances described above, and the like so that the optical resonant structure works well. Light emitted from the light-emitting layer 32 is repeatedly reflected between the reflective layer 52 and the counter electrode 33. Intensity of light having a wavelength corresponding to an optical distance between the reflective layer 52 and the counter electrode 33 is increased. The increased light is emitted from the counter electrode 33 to the +Z direction side via a counter substrate (not illustrated) disposed further on the +Z direction side than the sealing layer 60 and the color filter layer.

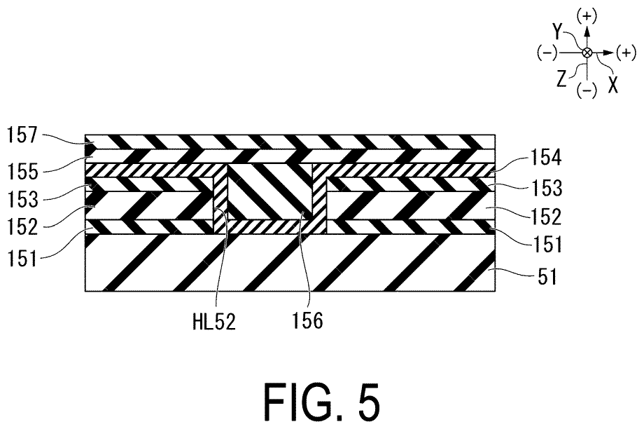

Next, with reference to FIGS. 5 to 12, a stacked structure of the insulating layer 157 to the conductive layer 133 in the Z-axis of the display unit 12 is illustrated. Each drawing from FIG. 5 to FIG. 12 is a cross-sectional view for explaining a manufacturing process of the stacked structure of the insulating layer 157 to the conductive layer 133 in the Z-axis, and is a view corresponding a case when viewed from the line C1-C1 illustrated in FIG. 3.

As illustrated in FIG. 5, at an entire surface on the +Z direction side of the insulating layer 155 made of an insulating material such as silicon oxide, a similar insulating material such as silicon oxide is deposited, and the insulating layer 157 having the thickness of t57 is stacked above the insulating layer 155.

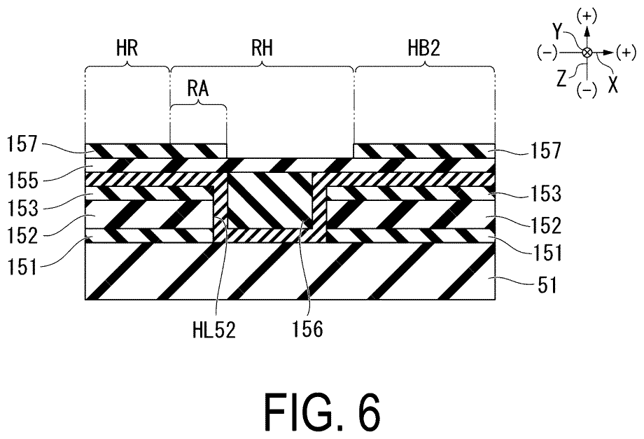

Next, a resist film (not illustrated) is provided above the insulating layer 157 in a region extending over the light-emitting region HR and the peripheral region RA in plan view, and above the insulating layer 157 in a region extending from a position spaced apart from the peripheral region RA in the +X direction, that is, to the light-emitting region HB2 side by an appropriate interval, to the light-emitting region HB2 in plan view. Subsequently, the insulating layer 157 exposed on the +Z direction side without being covered with the resist film is removed by patterning. As illustrated in FIG. 6, on a surface on the +Z direction side of the insulating layer 157, the insulating layer 157 in the light-emitting region HR and the peripheral region RA in plan view, and the insulating layer 157 in the light-emitting region HB2 separated therefrom in the X-axis are formed.

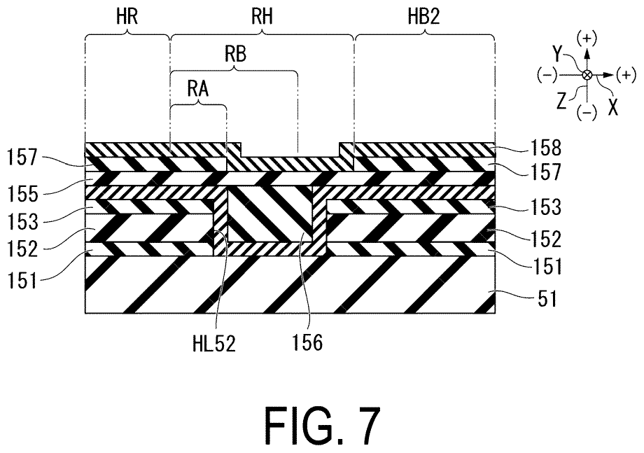

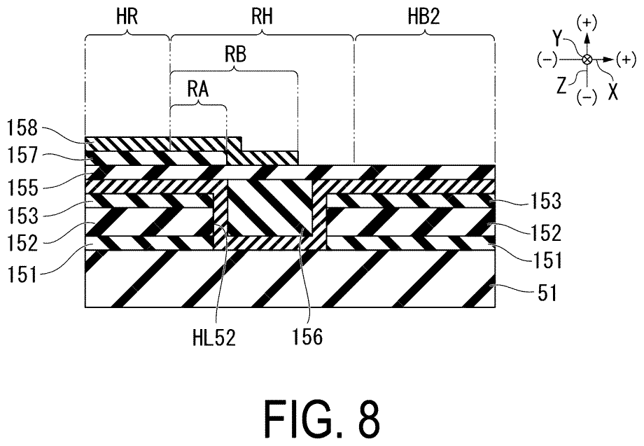

Next, as illustrated in FIG. 7, an insulating material such as silicon oxide is deposited at a surface parallel to the X-axis and the Y-axis of each of the insulating layers 155 and 157 exposed on the +Z direction side to form the insulating layer 158. Subsequently, a resist film (not illustrated) is provided above the insulating layer 158 in a region extending over the light-emitting region HR and the peripheral region RB. Subsequently, the insulating layer 157 or 158 exposed on the +Z direction side without being covered with the resist film is removed by patterning. As illustrated in FIG. 8, in plan view, the insulating layer 157 in the region extending over the light-emitting region HR and the peripheral region RA, and the insulating layer 158 extending over the light-emitting region HR and the peripheral region RB are formed.

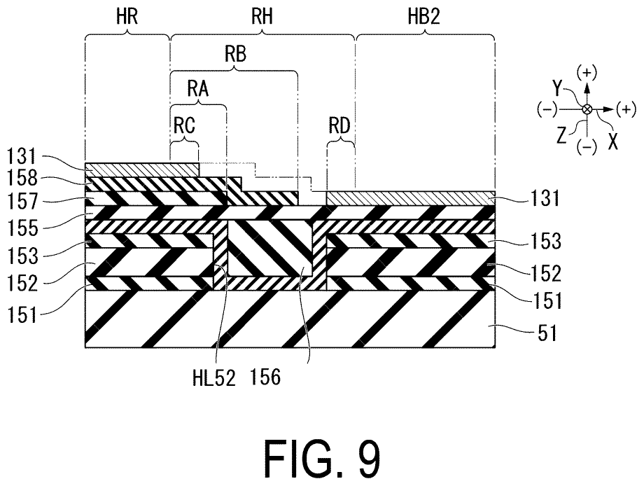

Next, as illustrated in FIG. 9, the conductive layer 131 made of ITO or the like is formed above the insulating layer 158 overlapping the light-emitting region HR and the peripheral region RC in plan view, and above the insulating layer 155 overlapping the light-emitting region HB2 and the peripheral region RD in plan view. In this process, the conductive layer 131 may be directly formed in each region, or the conductive layer 131 may be stacked over the entire light-emitting regions HR, HB2, and the peripheral region RH illustrated in FIG. 8, and then a portion of the conductive layer 131 indicated by a two-dot chain line between the peripheral regions RC and RD in plan view may be removed.

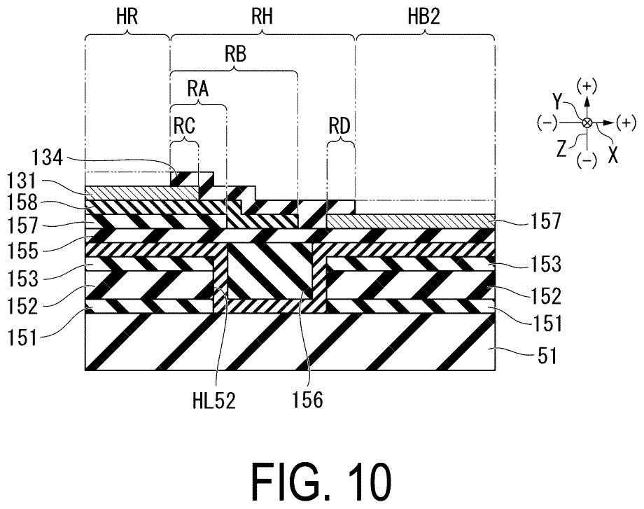

Next, as illustrated in FIG. 10, the insulating layer 134 made of silicon oxide or the like is formed above the conductive layer 131, above the insulating layer 158, and above the insulating layer 155 in the peripheral region RH in plan view.

In this process, the insulating layer 134 may be directly formed above each layer in the peripheral region RH, or the insulating layer 134 may be stacked over the entire light-emitting regions HR, HB2, and the peripheral region RH illustrated in FIG. 9, and then the insulating layer 134 of a portion in the light-emitting region HR or HB2 indicated by a two-dot chain line in plan view may be removed.

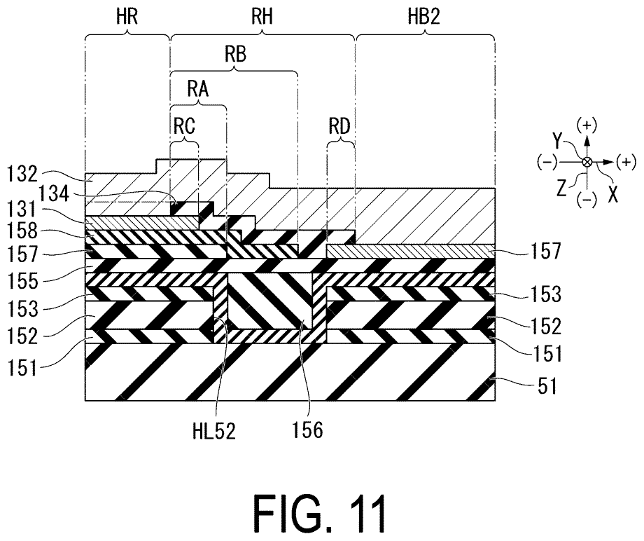

Next, as illustrated in FIG. 11, the hole-injection layer, the hole transport layer, the organic light-emitting layer, and the electron transport layer (not illustrated) are sequentially formed with predetermined thicknesses above the conductive layer 131 in each of the light-emitting regions HR and HB1, and above the insulating layer 134 in the peripheral region RH, thereby forming the conductive layers 132. A plurality of steps are formed at a front surface of each layer included in the conductive layer 132 on the +Z direction side, and at a front surface of the conductive layer 132 on the +Z direction side, in accordance with a step of the insulating layer 158 and a step of the insulating layer 134.

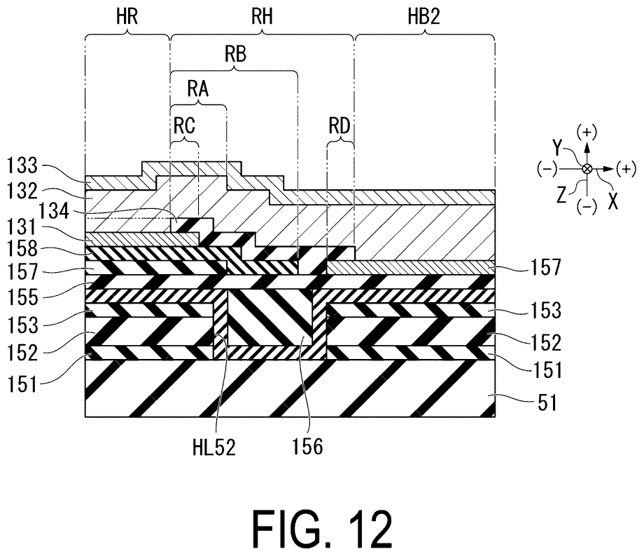

Next, as illustrated in FIG. 12, a translucent conductive material containing magnesium and silver is stacked with predetermined thickness above the conductive layer 132 in each of the light-emitting regions HR, HB1, and the peripheral region RH to form the conductive layer 133. Thereafter, the sealing layer 60 is stacked above the conductive layer 132 in each of the light-emitting regions HR, HB1, and the peripheral region RH, and thus the structure of the element substrate 5 of the display unit 12 illustrated in FIG. 4 is cleaned.

The electro-optical device 1 of the embodiment described above includes a first electrode 201, a first reflective layer 202, a first pixel electrode 211, a second reflective layer 203, a second pixel electrode 212, the light-emitting layer 32, and an insulating layer 250. In the electro-optical device 1, the counter electrode 33 corresponds to the first electrode 201, and is translucent to visible light including red light, green light, and blue light. The reflection enhancing layer 53 overlapping the light-emitting region HR in plan view is provided above the first reflective layer 202. The pixel electrode 31 overlapping the light-emitting region HR in plan view corresponds to the first pixel electrode 211, and is provided between the first electrode 201 and the first reflective layer 202 in the Z-axis. The reflection enhancing layer 53 overlapping the light-emitting region HB2 in plan view is provided above the second reflective layer 203. The pixel electrode 31 overlapping the light-emitting region HB1 in plan view corresponds to the second pixel electrode 212, and is provided between the first electrode 201 and the second reflective layer 203 in the Z-axis. The light-emitting layer 32 is provided between the first electrode 201 formed of the counter electrode 33, the first pixel electrode 211 formed of the pixel electrode 31 in the light-emitting region HR, and the second pixel electrode 212 formed of the pixel electrode 31 in the light-emitting region HB1 in the Z-axis. The insulating layer 250 has, for example, an insulating stacked structure of the first optical distance adjustment layer 57 formed of the insulating layer 157 and the second optical distance adjustment layer 58 formed of the insulating layer 158, and is provided between the first pixel electrode 211 and the first reflective layer 202 in the Z-axis. The insulating layer 250 extends from the first pixel electrode 211 provided in the light-emitting region HR and the peripheral region RC and between the first pixel electrode 211 and the second pixel electrode 212 provided in the peripheral region RD and the light-emitting region HB1 in plan view. A front surface 250a on the +Z direction side of the insulating layer 250, that is, a surface on the light-emitting layer 32 side includes the plurality of steps ST1 and ST2 between the first pixel electrode 211 and the second pixel electrode 212, that is, between the regions RC and RD in plan view.

In the electro-optical device 1 of the embodiment, the optical distance adjustment layer having the stacked structure of the first optical distance adjustment layer 57 and the second optical distance adjustment layer 58 is provided in the light-emitting region HR from which red light is emitted. The thickness t57 of the first optical distance adjustment layer 57 and the thickness t58 of the second optical distance adjustment layer 58 are appropriately adjusted so that the optical resonant structure for red light by the reflective layer 52 and the counter electrode 33 in the light-emitting region HR functions well, and red light in the optical resonant structure is efficiently extracted. On the other hand, an optical distance adjustment layer is not provided in a light-emitting region B2 from which blue light having a shorter wavelength than red light is emitted. In plan view, the first optical distance adjustment layer 57 of the insulating layer 250 is provided in the light-emitting region HR, and the peripheral region RA of the peripheral region RH between the light-emitting region HR and the light-emitting region HB2. The second optical distance adjustment layer 58 of the insulating layer 250 extends in the light-emitting region HR, and the peripheral region RB of the peripheral region RH. In plan view, the peripheral region RB is a region extending from the light-emitting region HR closer to the light-emitting region HB1 side than the peripheral region RA. A surface of the insulating layer 250 on the +Z direction side, that is, the front surface 250a includes the step ST1 at an end of the region RA on the light-emitting region HB1 side in plan view, and the step ST2 at an end of the region RB on the light-emitting region HB1 side in plan view.

In the electro-optical device 1 of the embodiment, the insulating layer 134 covers the first optical distance adjustment layer 57 and the second optical distance adjustment layer 58 in the peripheral region RH, and a front surface 134a of the insulating layer 134 interposed between the optical distance adjustment layers and the light-emitting layer 32 includes the steps ST11 and ST12. In the electro-optical device 1 of the embodiment, the front surface 134a of the insulating layer 134 includes, for example, the two steps ST11 and ST12, and a change in a thickness t32 of the light-emitting layer 32 in the peripheral region RH is gradual as compared with a case where the front surface 134a of the insulating layer 134 includes only one step or a case where no step is provided. That is, when moving along the X-axis from the light-emitting region HR toward the light-emitting region HB1 in plan view, the thickness t32 of the light-emitting layer 32 changes through a plurality of stages.

According to the electro-optical device 1 of the embodiment, as described above, the thickness t32 of the light-emitting layer 32 in the peripheral region RH changes through a plurality of stages, and do not become locally thinner as compared with the thickness t32 of the light-emitting layer 32 in the light-emitting region HR or HB1. As a result, resistance in the light-emitting layer 32 in the peripheral region RH is less likely to decrease, and it is possible to prevent an unintended current from flowing between the pixel electrode 31 serving as the positive electrode and the counter electrode 33 serving as the negative electrode in the peripheral region RH. As a result, according to the electro-optical device 1 of the embodiment, it is possible to prevent unnecessary peripheral light emission from occurring in the peripheral region RH of the sub-pixel Px. Therefore, according to the electro-optical device 1 of the embodiment, it is possible to suppress a decrease in color reproducibility of the electro-optical device 1.

Although not illustrated, a step due to the step ST2 of the front surface 250a of the insulating layer 250 may be formed at the front surface 134a of the insulating layer 134 provided between the first optical distance adjustment layer 57 and the second pixel electrode 212 in plan view.

The insulating layer 134 is provided to reliably ensure insulation between the electrodes when the first pixel electrode 211 and the second pixel electrode 212 are close to each other in plan view, but may be omitted. When the insulating layer 134 is not provided, the thickness t32 of the light-emitting layer 32 gradually changes between the first pixel electrode 211 and the second pixel electrode 212 in plan view due to the steps ST1 and ST2 of the front surface 250a of the insulating layer 250. As a result, according to the electro-optical device 1 of the embodiment, it is possible to prevent unnecessary peripheral light emission from occurring in the peripheral region RH of the sub-pixel Px. By appropriately adjusting positions of the steps ST1 and ST2 in the X-axis, the thickness t32 of the light-emitting layer 32 can be gradually changed through a plurality of stages.

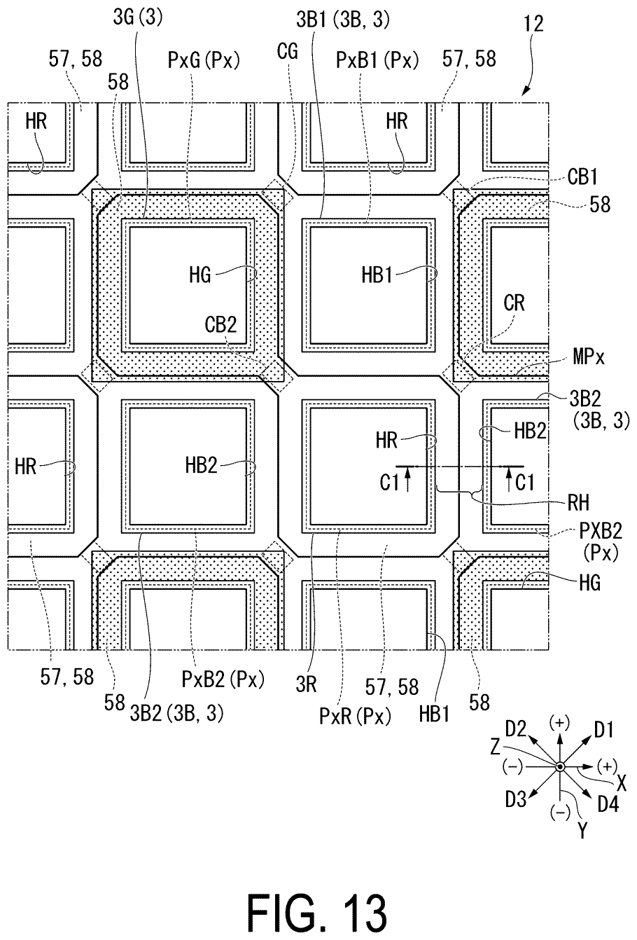

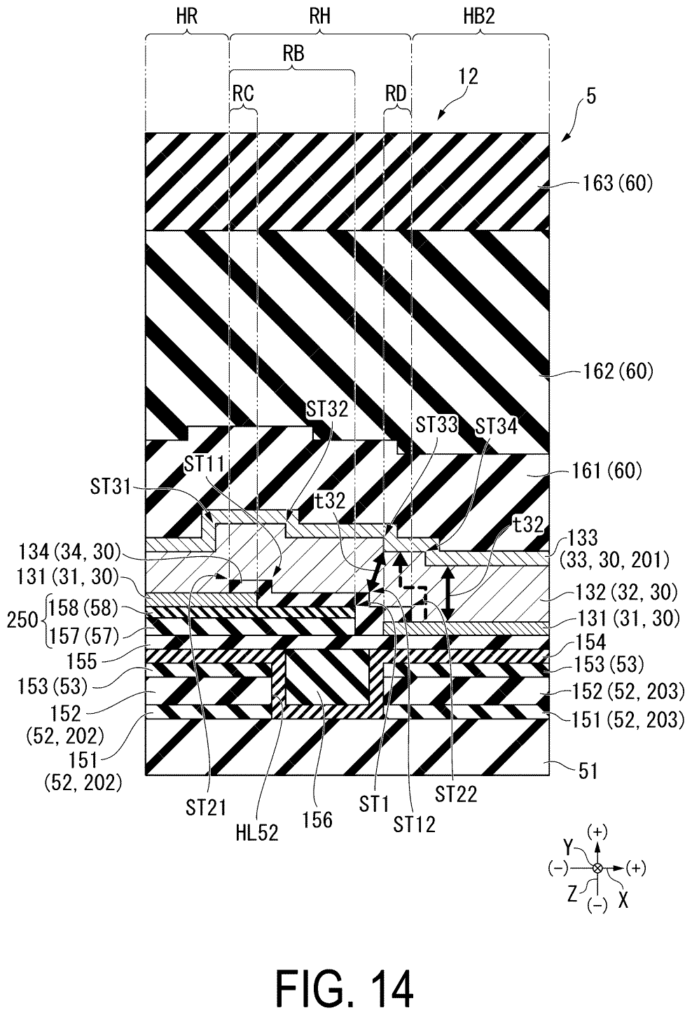

FIG. 13 is a plan view of the display unit 12 of an electro-optical device of the related art. FIG. 14 is a cross-sectional view of a part of the element substrate 5 of the display unit 12 of the electro-optical device of the related art, and is a diagram corresponding to a case when viewed along the line C1-C1 illustrated in FIG. 3. As illustrated in FIGS. 13 and 14, in a display unit of the electro-optical device of the related art, the first optical distance adjustment layer 57 formed of the insulating layer 157 and the second optical distance adjustment layer 58 formed of the insulating layer 158 are provided in the light-emitting region HR and the peripheral region RB, and are formed so as to overlap each other in plan view. That is, an end of the first optical distance adjustment layer 57 on the light-emitting region B2 side and an end of the second optical distance adjustment layer 58 on the light-emitting region B2 side overlap each other in plan view. The insulating layer 250 includes only one step ST1. In the configuration of the electro-optical device of the related art, the thickness t32 of the light-emitting layer 32 is locally smaller at the step ST1 as compared with a periphery in plan view. For this reason, resistance decreases in a vicinity of the step ST1, a current flows around to a gap between a portion serving as a positive electrode and a portion serving as a negative electrode, and the current flows in the peripheral region RH. As a result, unnecessary peripheral light emission having a wavelength different from that of red light or blue light is generated in an opening region of a sub-pixel, that is, in the peripheral region RH of the light-emitting region HR or HB1. As a result, in the electro-optical device of the related art, color reproducibility is reduced.

In the electro-optical device 1 of the embodiment, the light-emitting layer 32 overlapping the first electrode 201 formed of the conductive layer 133, and the first pixel electrode 211 formed of the pixel electrode 31 provided in the light-emitting region HR in plan view emits red light. The light-emitting layer 32 overlapping the first electrode 201 and the second pixel electrode 212 formed of the pixel electrode 31 provided in the light-emitting region HB1 in plan view emits blue light.

With respect to color light of three primary colors, a difference between a peak wavelength of red light and a peak wavelength of blue light is larger than a difference between a peak wavelength of green light and the peak wavelength of the red light or blue light. In the electro-optical device 1 of the embodiment, the optical distance adjustment layer having the stacked structure including at least two layers of the first optical distance adjustment layer 57 and the second optical distance adjustment layer 58 is provided in the light-emitting region HR and the peripheral region RA as a part of the peripheral region RH, instead of a single layer of an optical distance adjustment layer, in accordance with a difference between an optical distance of red light of the optical resonant structure in the light-emitting region HR and an optical distance of blue light in the optical resonant structure in the light-emitting region HB1. The second optical distance adjustment layer 58 is also provided on a side closer to the light-emitting region HB1 than the peripheral region RA in plan view, that is, in the peripheral region RB on the second pixel electrode 212 side. According to the electro-optical device 1 of the embodiment, it is possible to easily adjust a position of the light-emitting layer 32 emitting red light in the Z-axis with respect to the light-emitting layer 32 emitting blue light, that is, a height in the display unit 12, by the stacked structure of the first optical distance adjustment layer 57 and the second optical distance adjustment layer 58. By appropriately setting the thickness t57 of the first optical distance adjustment layer 57 and the thickness t58 of the second optical distance adjustment layer 58 in consideration of the peak wavelengths of the red and blue light, an optical distance difference between a resonator length in the light-emitting region HR of red light and a resonator length in the light-emitting region HB1 of blue light can be easily adjusted. Therefore, it is possible to suppress a decrease in color reproducibility of the electro-optical device 1.

In the electro-optical device 1 of the embodiment, the insulating layer 250 includes the first optical distance adjustment layer 57 formed of the insulating layer 157 and the second optical distance insulating layer 58 formed of the insulating layer 158. The first optical distance adjustment layer 57 is provided between the first pixel electrode 211 and the first reflective layer 202 in the Z-axis, and is further provided in the peripheral region RA from the first pixel electrode 211 in plan view. The peripheral region RA extends at least between the first pixel electrode 211 and the second pixel electrode 212 in a plan view and, to be specific, is a region on the light-emitting region HR side between the light-emitting region HR and the light-emitting region HB2 in the peripheral region RH. The second optical distance adjustment layer 58 is provided on the first pixel electrode 211 side of the first optical distance adjustment layer 57 in the Z-axis, specifically, is provided between the first optical distance adjustment layer 57 and the first pixel electrode 211. The second optical distance adjustment layer 58 is provided spanning from the first pixel electrode 211 to the peripheral region RB extending closer to the second pixel electrode 212 side than the peripheral region RA in plan view. The insulating layer 250 having the stacked structure of the first optical distance adjustment layer 57 and the second optical distance adjustment layer 58 includes the step ST1 formed of the second optical distance adjustment layer 58 covering an end portion of the first optical distance adjustment layer 57 on the second pixel electrode 212 side in plan view, and the step ST2 formed of an end portion of the second optical distance adjustment layer 58 on the second pixel electrode 212 side in plan view.

According to the electro-optical device 1 of the embodiment, a position of an end of the first optical distance adjustment layer 57 on the second pixel electrode 212 side in plan view in the peripheral region RH, and a position of an end of the second optical distance adjustment layer 58 on the second pixel electrode 212 side in plan view in the peripheral region RH are adjusted, and the thickness t32 of the light-emitting layer 32 can be gradually and easily changed through a plurality of steps. Therefore, it is possible to suppress a decrease in color reproducibility of the electro-optical device 1.

The insulating layer 250 is not limited to the stacked structure of the first optical distance adjustment layer 57 and the second optical distance adjustment layer 58 as described above, and may be configured by one insulating layer in the Z-axis and a thickness direction, and may include a plurality of steps at a surface of the one insulating layer on the light-emitting layer 32 side, that is, at a front surface on the +Z direction side.

In the electro-optical device 1 of the embodiment, the insulating layer 250 includes the step ST1 as a first step and the step ST2 as a second step. The step ST1 is formed closer to the first pixel electrode 211 side than an intermediate position between the first pixel electrode 211 and the second pixel electrode in plan view. In plan view, the intermediate position between the first pixel electrode 211 and the second pixel electrode is located at a position similar to the intermediate position CH between the light-emitting region HR and the light-emitting region HB2 of the display unit 12 of the electro-optical device 1, for example. The step ST2 is formed closer to the second pixel electrode side than the intermediate position between the first pixel electrode 211 and the second pixel electrode in plan view, and is formed closer to the second reflective layer 203 side, that is, closer to the −Z direction side than the step ST1 in a thickness direction parallel to the Z-axis.

According to the electro-optical device 1 of the embodiment, the step ST1 is disposed on the first pixel electrode 211 side and the step ST2 is disposed on the second pixel electrode 212 side with the intermediate position CH interposed therebetween in the X-axis, and the thickness t32 of the light-emitting layer 32 between the first pixel electrode 211 and the second pixel electrode 212 in the X-axis can be gradually changed. Therefore, it is possible to suppress a decrease in color reproducibility of the electro-optical device 1.

In the electro-optical device 1 of the embodiment, the insulating layer 250 includes the step ST1 as a first step and the step ST2 as a second step. The step ST1 or ST2 is provided between the first reflective layer 202 and the second reflective layer 203 in plan view and the X-axis, and to be specific, overlaps the insulating layer 154 or 156 in the hole HL52 formed between the first reflective layer 202 and the second reflective layer 203 in plan view and the X-axis.

According to the electro-optical device 1 of the embodiment, even when a portion of the light-emitting layer 32 is generated in the peripheral region RH where the thickness t32 is smaller than that in a periphery, even not locally, due to the steps ST1 and ST2 of the insulating layer 250, the first reflective layer 202 or the second reflective layer 203 does not overlap such a portion of the light-emitting layer 32 having the smaller thickness t32 on the −Z direction side. Therefore, even if peripheral light emission slightly occurs from the portion of the light-emitting layer 32 where the t32 is small, the light is unlikely to be emitted to the +Z direction side. Therefore, it is possible to suppress a decrease in color reproducibility of the electro-optical device 1.

### Electronic Apparatus

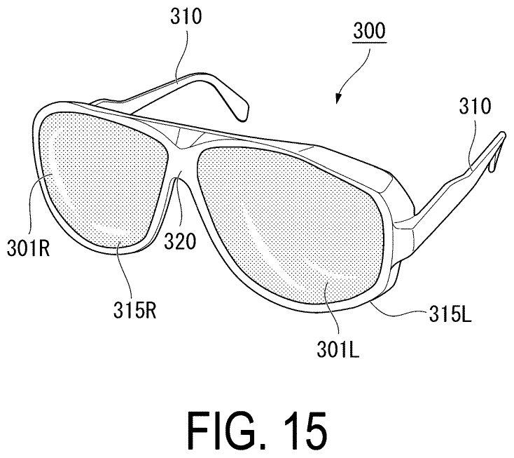

Next, an electronic apparatus of the embodiment will be described. FIG. 15 is a schematic view of a head-mounted display 300 as an example of the electronic apparatus of the embodiment. The head-mounted display 300 includes a temple 310, a bridge 320, a left-eye projection optical system 301L, and a right-eye projection optical system 301R. The projection optical system 301L is provided with a left-eye electro-optical element 1 (not illustrated). The projection optical system 301R is provided with the left-eye electro-optical element 1 (not illustrated).

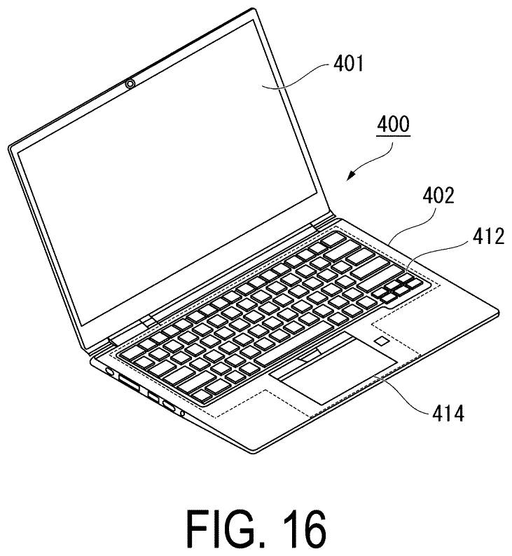

FIG. 16 is a schematic view of a personal computer 400 as another example of the electronic apparatus of the embodiment. The personal computer 400 includes a display 401 for displaying various desired images, and a main body 402 including an input device for the display 401 and various processing circuits. The main body 402 includes a keyboard 412 and a touch panel 414 as input devices.

As still another example of the electronic apparatus of the embodiment, for example, a smart phone, a television, an electronic notebook, electronic paper, or the like (not illustrated) may be used. The electro-optical device 1 described above can be applied to an electronic apparatus such as a printer, a scanner, a copying machine, or a video player.

According to the electronic apparatus including the head-mounted display 300 of the embodiment, since the above-described electro-optical device 1 is provided, it is possible to suppress peripheral light emission in the electro-optical device 1, and to suppress a decrease in color reproducibility.

Although the preferred embodiments of the disclosure have been described in detail above, the disclosure is not limited to the particular embodiments, and various variations and changes are possible within the scope of the gist of the disclosure as described in the claims.

### OVERVIEW OF PRESENT DISCLOSURE

An overview of the present disclosure is added below.

### Supplementary Note 1

An electro-optical device including a transflective first electrode, a first reflective layer, a first pixel electrode provided between the first electrode and the first reflective layer, a second reflective layer, a second pixel electrode provided between the first electrode and the second reflective layer, a light-emitting layer provided between the first electrode, and the first pixel electrode and the second pixel electrode, and an insulating layer provided between the first pixel electrode and the first reflective layer, wherein the insulating layer extends from the first pixel electrode and between the first pixel electrode and the second pixel electrode in plan view, and a surface of the insulating layer on the light-emitting layer side includes a plurality of steps between the first pixel electrode and the second pixel electrode in plan view.

According to the configuration of Supplementary Note 1, it is possible to gradually change a thickness of the light-emitting layer in a peripheral region of the first pixel electrode through a plurality of stages as compared with a case where a surface of the insulating layer on the light-emitting layer side has only one step or a case where no step is provided. According to the configuration of Supplementary Note 1, it is possible to suppress a decrease in color reproducibility of the electro-optical device.

### Supplementary Note 2

The electro-optical device according to Supplementary Note 1, wherein the light-emitting layer overlapping the first electrode and the first pixel electrode in plan view emits red light, and the light-emitting layer overlapping the first electrode and the second pixel electrode in plan view emits blue light.

According to the configuration of Supplementary Note 2, a thickness of the insulating layer can be set appropriately and with a margin, in accordance with a difference between a resonator length of an optical resonant structure in a red light-emitting region and a resonator length of an optical resonant structure in a blue light-emitting region, and a plurality of steps can be formed at the surface of the insulating layer on the light-emitting layer side.

### Supplementary Note 3

The electro-optical device according to Supplementary Note 1 or 2, wherein the insulating layer includes a first optical distance adjustment layer provided between the first pixel electrode and the first reflective layer, and provided in a first region extending from the first pixel electrode and between the first pixel electrode and the second pixel electrode in plan view, and a second optical distance adjustment layer provided on the first pixel electrode side of the first optical distance adjustment layer, and provided spanning from the first pixel electrode to a second region extending closer to the second pixel electrode side than the first region in plan view.

According to the configuration of Supplementary Note 3, at least two steps can be formed at the surface of the insulating layer on the light-emitting layer side by an end of the first optical distance adjustment layer on the second pixel electrode side and an end of the second optical distance adjustment layer on the second pixel electrode side in plan view.

### Supplementary Note 4

The electro-optical device according to any one of Supplementary Notes 1 to 3, wherein the insulating layer includes a first step and a second step, the first step is formed closer to the first pixel electrode side than an intermediate position between the first pixel electrode and the second pixel electrode in plan view, and the second step is formed closer to the second pixel electrode side than the intermediate position in plan view, and is formed closer to the second reflective layer side than the first step in a thickness direction.

According to the configuration of Supplementary Note 4, it is possible to form the first step and the second step at an appropriate interval at the surface of the insulating layer on the light-emitting layer side between the first pixel electrode and the second pixel electrode in plan view.

### Supplementary Note 5

The electro-optical device according to any one of Supplementary Notes 1 to 4, wherein the insulating layer includes the first step and the second step, and the first step and the second step are provided between the first reflective layer and the second reflective layer in plan view.

According to the configuration of Supplementary Note 5, even if peripheral light emission slightly occurs in a thin portion of the light-emitting layer in the peripheral region of the first pixel electrode, the peripheral light emission is not reflected by the first reflective layer or the second reflective layer, and light is not emitted to a counter electrode side.

### Supplementary Note 6

An electronic apparatus including the electro-optical device according to any one of Supplementary Notes 1 to 5.

According to the configuration of Supplementary Note 6, it is possible to suppress peripheral light emission in an electronic optical device of the electronic apparatus and suppress a decrease in color reproducibility.

What is claimed is:

1. An electro-optical device, comprising:
a transflective first electrode;
a first reflective layer;
a first pixel electrode provided between the first electrode and the first reflective layer;
a second reflective layer;
a second pixel electrode provided between the first electrode and the second reflective layer;
a light-emitting layer provided between the first electrode, and the first pixel electrode and the second pixel electrode; and
an insulating layer provided between the first pixel electrode and the first reflective layer, wherein
the insulating layer extends from the first pixel electrode and between the first pixel electrode and the second pixel electrode in plan view, and
a surface of the insulating layer on the light-emitting layer side includes a plurality of steps between the first pixel electrode and the second pixel electrode in plan view.

2. The electro-optical device according to claim 1, wherein
the light-emitting layer overlapping the first electrode and the first pixel electrode in plan view emits red light, and
the light-emitting layer overlapping the first electrode and the second pixel electrode in plan view emits blue light.

3. The electro-optical device according to claim 1, wherein
the insulating layer includes
a first optical distance adjustment layer provided between the first pixel electrode and the first reflective layer, and provided in a first region extending from the first pixel electrode and between the first pixel electrode and the second pixel electrode in plan view, and
a second optical distance adjustment layer provided on the first pixel electrode side of the first optical distance adjustment layer, and provided spanning from the first pixel electrode to a second region extending closer to the second pixel electrode side than the first region in plan view.

4. The electro-optical device according to claim 1, wherein
the insulating layer includes a first step and a second step,
the first step is formed closer to the first pixel electrode side than an intermediate position between the first pixel electrode and the second pixel electrode in plan view, and
the second step is formed closer to the second pixel electrode side than the intermediate position in plan view, and is formed closer to the second reflective layer side than the first step in a thickness direction.

5. The electro-optical device according to claim 1, wherein
the insulating layer includes a first step and a second step, and
the first step and the second step are provided between the first reflective layer and the second reflective layer in plan view.

6. An electronic apparatus comprising the electro-optical device according to claim 1.
